(19) United States
(12) Patent Application Publication
(10) Pub. No.: US 2025/0171891 A1
(43) Pub. Date: May 29, 2025

(54) METHOD OF FILLING GAPS ON SUBSTRATE SURFACE USING PLASMA

(71) Applicant: ASM IP Holding B.V., Almere (NL)

(72) Inventor: Sho Ichinose, Yokohama-shi (JP)

(21) Appl. No.: 18/958,134

(22) Filed: Nov. 25, 2024

Related U.S. Application Data
(60) Provisional application No. 63/603,165, filed on Nov. 28, 2023.

(51) Int. Cl. C23C 16/04; C23C 16/40; C23C 16/50; C23C 16/56; H01L 21/02; H01L 21/311

(52) U.S. Cl. CPC C23C 16/045; C23C 16/401; C23C 16/50; C23C 16/56; H01L 21/02164; H01L 21/02274; H01L 21/31116

(57) ABSTRACT

A method of forming a silicon oxide film on a substrate is provided. The method may comprise steps of: (a) placing a substrate on a susceptor in a reaction chamber; wherein the substrate comprises a gap; (b) a deposition step comprising: providing a continuous flow of a silicon-containing precursor to the reaction chamber; providing a continuous flow of an oxidizing gas to the reaction chamber; and depositing a portion of a silicon oxide film on the substrate by providing a plasma power to the silicon-containing precursors and the oxidizing precursor; and (c) an etching step comprising: etching a part of the portion by providing an etching gas to the reaction chamber; wherein the etching gas is activated by a remote plasma unit, and wherein the remote plasma unit is fluidly coupled to the reaction chamber.

### CROSS-REFERENCE TO RELATED APPLICATIONS

This application claims priority to U.S. Provisional Patent Application Ser. No. 63/603,165 filed Nov. 28, 2023 titled METHOD OF FILLING GAPS ON SUBSTRATE SURFACE USING PLASMA, the disclosure of which is hereby incorporated by reference in its entirety.

### FIELD OF INVENTION

The present disclosure generally relates to methods of forming structures suitable for use in the manufacture of electronic devices. More particularly, examples of the disclosure relate to methods of filling gaps using plasma on substrate surface.

### BACKGROUND OF THE DISCLOSURE

Chip on wafer is used as part of an advanced 3D packaging process. Several small chips are put on one large chip or wafer by micro bump or direct bonding. In this process, filling a gap between the small chips is required. A plasma enhanced chemical vapor deposition (PECVD) process can be used to fill the gap when a width of the gap is between 30 um and 650 um and a depth of the gap is between 5 um and 50 um.

A silicon oxide film is commonly used to fill the gap. An etch back sequence may be necessary because step coverage by PECVD process is not good.

Accordingly, improved methods for filling gaps are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a method of forming a silicon oxide film on a substrate is provided. The method may comprise steps of: (a) placing a substrate on a susceptor in a reaction chamber; wherein the substrate comprises a gap; (b) a deposition step comprising: providing a continuous flow of a silicon-containing precursor to the reaction chamber; providing a continuous flow of an oxidizing gas to the reaction chamber; and depositing a portion of a silicon oxide film on the substrate by providing a plasma power to the silicon-containing precursors and the oxidizing precursor; and (c) an etching step comprising: etching a part of the portion by providing an etching gas to the reaction chamber; wherein the etching gas is activated by a remote plasma unit, and wherein the remote plasma unit is fluidly coupled to the reaction chamber.

In accordance with further examples of the disclosure, the method may further comprise repeating step (b) and step (c) until the silicon oxide film fills up the gap.

In accordance with further examples of the disclosure, the silicon-containing precursor may comprise at least one of SiH4, SiF4, Si2H6, TEOS, TMCTS, OMCTS, DMDMOS, 3 MS, 4 MS, or combinations thereof.

In accordance with further examples of the disclosure, the oxidizing gas may comprise at least one of: O2, O3, N2O, N2O4, NxOy, CO, CO2, H2O, H2O2, or combinations thereof.

In accordance with further examples of the disclosure, the etching gas may comprise fluorine-containing gas.

In accordance with further examples of the disclosure, the flow rate of the etching gas may be between 0.5 and 5 slm.

In accordance with further examples of the disclosure, the fluorine-containing gas may comprise at least one of NF3, C2F6, CF4, or combinations thereof.

In accordance with further examples of the disclosure, the fluorine-containing gas may comprise NF3 and the flow rate of NF3 is between 3 and 5 slm.

In accordance with further examples of the disclosure, the step (b) and (c) may be conducted in the same chamber.

In accordance with further examples of the disclosure, the step (c) may be conducted in a second reaction chamber.

In accordance with further examples of the disclosure, a pressure for the step (b) may be lower than that for the step (c).

In accordance with further examples of the disclosure, a pressure for the step (c) may be between 700 and 900 Pa.

In accordance with further examples of the disclosure, the gases may be provided to the reaction chamber through a shower plate.

In accordance with further examples of the disclosure, a gap between the shower plate and susceptor during the step (c) may be narrower than that during the step (b).

In accordance with further examples of the disclosure, the distance during the step (c) may be between 5.0 mm and 7.0 mm.

In accordance with further examples of the disclosure, a width of the gap in the substrate may be between 30 um and 650 um and a depth of the gap is between 5 um and 50 um.

In accordance with further examples of the disclosure, a substrate processing apparatus may be provided to perform the steps.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a timing sequence in accordance with exemplary embodiments of the disclosure.

FIG. 3a illustrates a scanning electron microscope image of structure after deposition step.

FIG. 3b illustrates a scanning electron microscope image of structure after etching step to the structure in FIG. 3a by direct plasma.

FIG. 3c illustrates a scanning electron microscope image of structure in accordance with exemplary embodiments of the disclosure.

FIG. 4 illustrates a graph showing process conditions of etching step.

FIG. 5 illustrates a plasma system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that can excite a precursor when plasma power is applied.

As used herein, the term “film” and “thin film” may refer to any continuous or non- continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

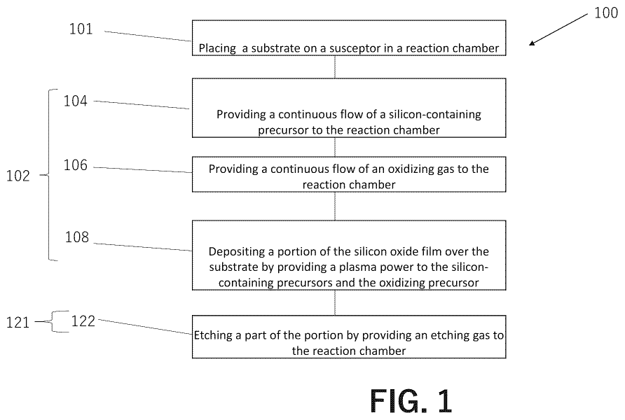

FIG. 1 illustrates a method 100 of forming a silicon oxide film on a substrate in accordance with exemplary embodiments of the disclosure. The method 100 includes steps of: placing a substrate on a susceptor in a reaction chamber (step 101) and a deposition step 102 comprising: providing a continuous flow of a silicon-containing precursor to the reaction chamber (step 104); providing a continuous flow of an oxidizing gas to the reaction chamber (step 106); and depositing a portion of the silicon oxide film over the substrate by providing a plasma power to the silicon-containing precursors and the oxidizing precursor (step 108). The method further includes an etching step 121 comprising etching a part of the portion by providing an etching gas to the reaction chamber The etching gas may be activated by a remote plasma unit.

During step 101, a substrate is placed on a susceptor in a reaction chamber. The substrate may include a gap. A width of the gap may be between 30 um and 650 um and a depth of the gap may be between 5 um and 50 um. In accordance with examples of the disclosure, the reaction chamber can form part of a chemical vapor deposition reactor, such as a plasma-enhanced chemical vapor deposition (PECVD) reactor. Various steps of methods described herein can be performed within a single reaction chamber or can be performed in multiple reaction chambers, such as reaction chambers of a cluster tool.

During step 101, the substrate can be brought to a desired temperature and the reaction chamber can be brought to a desired pressure, such as a temperature and pressure suitable for subsequent steps. By way of examples, a temperature (e.g., of a substrate or a substrate support) within a reaction chamber can be 100° C. to 400° C. A pressure within the reaction chamber can be from 300 to 1,000 Pa.

During providing the silicon-containing precursor to the reaction chamber step 104, the precursor for forming the silicon oxide film is continuously introduced into the reaction chamber. Exemplary silicon-containing precursor may comprise: SiH4, SiF4, Si2H6, TEOS, TMCTS, OMCTS, DMDMOS, 3MS, 4MS, or combinations thereof.

During step 106, the oxidizing gas may be continuously provided to the reaction chamber. The oxidizing gas may be flowed to the reaction chamber at the same time or overlapping in time with the step of providing one or more precursors to the reaction chamber. Exemplary oxidizing gas may comprise one or more of: O2, O3, N2O, N2O4, NxOy, CO, CO2, H2O, or combination thereof.

During the step of providing a plasma power to the silicon-containing precursor and oxidizing gas within the reaction chamber (step 108), the plasma may be generated using a direct plasma system, described in more detail below. A power used to generate the plasma during step 108 can be between about 200 W and about 2,000 W. A frequency of the power can range from 1 from 200 kHz to 30 MHz with dual RF power sources (e.g. LRF 400 kHz and HRF 13.56 MHZ).

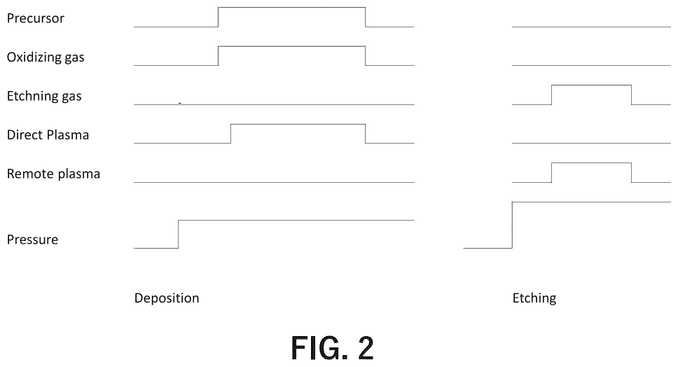

FIG. 2 illustrates a timing sequence in accordance with exemplary embodiments of the disclosure. During the period when the precursor and the oxidizing are being provided, the plasma power can be provided.

During step 121, the etching gas may be provided to the reaction chamber. The etching gas may comprise a fluorine-containing gas. The fluorine-containing gas may comprise at least one of NF3, C2F6, CF4, or combinations thereof. The deposition step 102 and the etching step 121 may be repeated until the silicon oxide film fills up the gap. A pressure within the reaction chamber during the etching step may be higher than that of the deposition process.

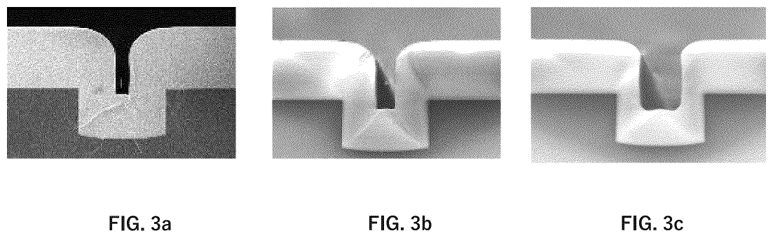

FIG. 3a illustrates a scanning electron microscope image of structure after deposition step by PECVD process. A gap after the deposition step is narrow. Therefore, an etching step is required to make the gap wider. FIG. 3b illustrates a scanning electron microscope image of structure after etching step by direct plasma. The gap may still be narrow even after direct plasma. FIG. 3c illustrates a scanning electron microscope image of structure in accordance with exemplary embodiments of the disclosure. The gap becomes wide by using remote plasma etching. Therefore, gap fill can be achieved by repeating the deposition step and this remote plasma based etching process.

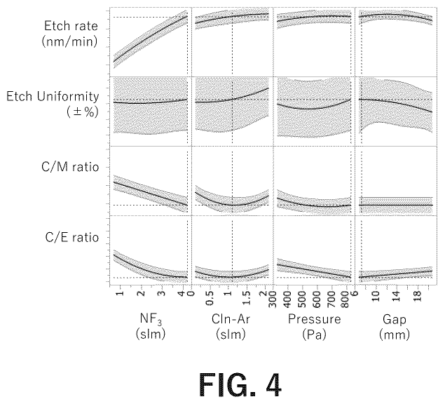

FIG. 4 illustrates a graph showing process conditions of etching step. The edge profile of the deposited film may be high after the deposition step. Increasing the amount of NF3 (e.g. between 3 and 5 slm), increasing the pressure (e.g. between 700 Pa and 900 Pa), and decreasing gap (e.g. between 5 mm and 7 mm) between the susceptor and shower plate are effective to obtain edge high etching rate during the etching step, resulting in improving the uniformity of the film.

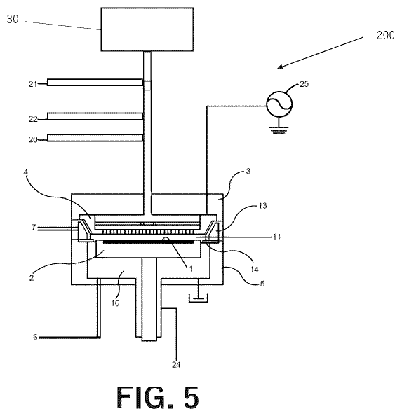

FIG. 5 illustrates a plasma reactor system 500 in accordance with exemplary embodiments of the disclosure is illustrated. The plasma reactor system 500 can be used to perform one or more steps or sub steps as described herein and/or to form one or more structures or portions thereof as described herein.

The plasma reactor system 200 may include a pair of electrically conductive flat-plate electrodes 4, 2 in parallel and facing each other in an interior 11 (reaction zone) of a reaction chamber 3. A plasma can be excited within the reaction chamber 3 by applying, for example, HRF power (e.g., 13.56 MHz or 27 MHz) and LRF power (e.g. 400 to 500 kHz) from a power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. The electrode 4 may serve as a gas distribution device, such as a shower plate. Reactant gas, dilution gas, if any, precursor gas, and/or the like may be introduced into reaction chamber 3 using one or more of a gas line 20, a gas line 21, and a gas line 22, respectively, and through the shower plate 4. Although illustrated with three gas lines, the reactor system 200 can include any suitable number of gas lines. A remote plasma unit 30 may be fluidly coupled to the reaction chamber 3. An etching gas may be introduced into the remote plasma unit 30. The etching gas may be activated by the remote plasma unit 30 and introduced into the reaction chamber 3 through the shower plate 4.

In the reaction chamber 3, a circular duct 13 with an exhaust line 7 may be provided, through which gas in the interior 11 of the reaction chamber 3 can be exhausted. Additionally, a transfer chamber 5, disposed below the reaction chamber 3, may be provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone may be provided (a gate valve through which a wafer is transferred into or from the transfer chamber 5 is omitted from this figure). The transfer chamber may be also provided with an exhaust line 6. In some embodiments, the deposition and etching steps may be performed in the same reaction space, so that two steps can continuously be conducted without exposing the substrate to air or other oxygen-containing atmosphere.

A skilled artisan will appreciate that the apparatus includes one or more controller(s) programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a multiple chamber reactor (two or more sections or compartments for processing wafers disposed close to each other) can be used, wherein a reactant gas and a noble gas can be supplied through a shared line, whereas a precursor gas can be supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a silicon oxide film on a substrate;
the method comprising steps of:
(a) placing a substrate on a susceptor in a reaction chamber;
wherein the substrate comprises a gap;
(b) a deposition step comprising:
providing a continuous flow of a silicon-containing precursor to the reaction chamber;
providing a continuous flow of an oxidizing gas to the reaction chamber; and
depositing a portion of a silicon oxide film on the substrate by providing a plasma power to the silicon-containing precursors and the oxidizing gas; and
(c) an etching step comprising:
etching a part of the portion by providing an etching gas to the reaction chamber;
wherein the etching gas is activated by a remote plasma unit, and wherein the remote plasma unit is fluidly coupled to the reaction chamber.

2. The method of claim 1, further comprising repeating step (b) and step (c) until the silicon oxide film fills up the gap.

3. The method of claim 1, wherein the silicon-containing precursor comprises at least one of SiH4, SiF4, Si2H6, TEOS, TMCTS, OMCTS, DMDMOS, 3MS, 4MS, or combinations thereof.

4. The method of claim 1, wherein the oxidizing gas comprises at least one of: O2, O3, N2O, N2O4, NxOy, CO, CO2, H2O, H2O2, or combinations thereof.

5. The method of claim 1, wherein the etching gas comprises a fluorine-containing gas.

6. The method of claim 1, wherein a flow rate of the etching gas is between 0.5 and 5 slm.

7. The method of claim 5, wherein the fluorine-containing gas comprises at least one of NF3,C2F6, CF4, or combinations thereof.

8. The method of claim 7, wherein the fluorine-containing gas comprises NF3 and a flow rate of NF3 is between 3 and 5 slm.

9. The method of claim 1, wherein the step (b) and (c) are conducted in the same reaction chamber.

10. The method of claim 1, wherein the step (c) is conducted in a second reaction chamber.

11. The method of claim 1, wherein a pressure for the step (b) is lower than that for the step (c).

12. The method of claim 11, wherein a pressure for the step (c) is between 700 and 900 Pa.

13. The method of claim 1, wherein the precursor and the gases are provided to the reaction chamber through a shower plate.

14. The method of claim 13, wherein a gap between the shower plate and the susceptor during the step (c) is narrower than that during the step (b).

15. The method of claim 14, wherein a distance during the step (c) is between 5.0 mm and 7.0 mm.

16. The method of claim 1, wherein a width of the gap in the substrate is between 30 um and 650 um and a depth of the gap is between 5 um and 50 um.

17. A substrate processing apparatus configured to perform the steps of claim 1.
